(19) United States
(12) Patent Application Publication
(10) Pub. No.: US 2011/0083734 A1
(43) Pub. Date: Apr. 14, 2011

(54) MODULE MOISTURE BARRIER

(75) Inventors: Benyamin Buller, Sylvania, OH (US); Markus Gloeckler, Perrysburg, OH (US); Scott McWilliams, Ottawa Hills, OH (US)

(73) Assignee: First Solar, Inc., Perrysburg, OH (US)

(21) Appl. No.: 12/901,188

(22) Filed: Oct. 8, 2010

Related U.S. Application Data
(60) Provisional application No. 61/250,356, filed on Oct. 9, 2009.

(51) Int. Cl. H01L 31/0224; H01L 31/18

(52) U.S. Cl. 136/256; 438/64; 257/E31.124

(57) ABSTRACT

A photovoltaic module may include a substrate; a semiconductor layer adjacent to the substrate; a lead foil adjacent to the semiconductor layer; a cover glass adjacent to the lead foil, where the cover glass includes a top surface, a bottom surface, and an opening, where the opening penetrates the top and bottom surfaces of the cover glass, and the opening includes an opening lateral dimension; and a barrier layer between the cover glass and the semiconductor layer, where the barrier layer includes a barrier lateral dimension, where the barrier lateral dimension is greater than the opening lateral dimension.

### CLAIM FOR PRIORITY

This application claims priority under 35 U.S.C. §119(e) to U.S. Provisional Patent Application Ser. No. 61/250,356 filed on Oct. 9, 2009, which is hereby incorporated by reference.

### TECHNICAL FIELD

The present invention relates to photovoltaic modules and methods of production.

### BACKGROUND

Photovoltaic modules can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic modules can also contain one or more transparent conductive oxide layers, which are also often conductors of electrical charge.

### DESCRIPTION OF DRAWINGS

FIG. 1 is a schematic of a photovoltaic module including a barrier material.

FIG. 2 is a schematic of a photovoltaic module including a barrier material.

FIG. 3 is a schematic of a photovoltaic module including a barrier material.

FIG. 4 is a schematic of a photovoltaic module including a barrier material.

### DETAILED DESCRIPTION

In general, a photovoltaic module may include a substrate; a semiconductor layer adjacent to the substrate; a lead foil adjacent to the semiconductor layer; a cover glass adjacent to the lead foil, where the cover glass includes a top surface, a bottom surface, and an opening, where the opening penetrates the top and bottom surfaces of the cover glass, and the opening includes an opening lateral dimension; and a barrier layer between the cover glass and the semiconductor layer, where the barrier layer includes a barrier lateral dimension, where the barrier lateral dimension is greater than the opening lateral dimension.

The photovoltaic module may have various optional features. For example, the barrier layer may include a strip of double-sided tape. The photovoltaic module may include a strip of double-sided tape between the semiconductor layer and the lead foil. The barrier layer may be positioned between the strip of double-sided tape and the semiconductor layer. The barrier layer may be positioned between the strip of double-sided tape and the lead foil. The barrier layer may include an insulative material. The photovoltaic module may include an insulative material. The barrier layer may be positioned on a back contact metal, where the photovoltaic module includes the back contact metal. The barrier layer may include multiple layers. The barrier layer may include an organic material, an oxide, or metal. The barrier layer may include an adhesive. The barrier layer may be effective as a moisture barrier. The barrier lateral dimension may extend a distance substantially equivalent to a lateral dimension of the photovoltaic module. The barrier lateral dimension may be greater than a moisture diffusion path length, where the moisture diffusion path length is defined by a length extending laterally away from a perimeter of the opening over which moisture is capable of diffusing. The photovoltaic module may include a cord plate assembly positioned on the top surface of the cover glass.

In general, a method of manufacturing a photovoltaic module may include depositing a semiconductor layer adjacent to a substrate; depositing a lead foil adjacent to the semiconductor layer; positioning a cover glass adjacent to the lead foil, where the cover glass includes a top surface, a bottom surface, and an opening, where the opening penetrates the top and bottom surfaces of the cover glass, and the opening includes an opening lateral dimension; and depositing a barrier layer between the cover glass and the semiconductor layer, where the barrier layer includes a barrier lateral dimension, where the barrier lateral dimension is greater than the opening lateral dimension.

The method may have various optional features. For example, the barrier layer may include a strip of double-sided tape. The method may include positioning a strip of double-sided tape between the semiconductor layer and the lead foil. The step of depositing a barrier layer may include placing the barrier layer between the strip of double-sided tape and the semiconductor layer. The step of depositing a barrier layer may include placing the barrier layer between the strip of double-sided tape and the lead foil. The barrier layer may include an insulative material. The method may include positioning an insulative material adjacent to the semiconductor layer. The step of depositing a barrier layer may include placing the barrier layer on a back contact metal, where the photovoltaic module includes the back contact metal. The barrier layer may include multiple layers. The barrier layer may include an organic material, an oxide, or metal. The barrier layer may include an adhesive. The barrier layer may be effective as a moisture barrier. The barrier lateral dimension may extend a distance substantially equivalent to a lateral dimension of the photovoltaic module. The barrier lateral dimension may be greater than a moisture diffusion path length, where the moisture diffusion path length is defined by a length extending laterally away from a perimeter of the opening over which moisture is capable of diffusing. The method may include positioning a cord plate assembly on the top surface of the cover glass.

In general, a photovoltaic module may also include a substrate; a semiconductor layer adjacent to the substrate; a strip of double-sided tape adjacent to the semiconductor layer; a lead foil adjacent to the strip of double-sided tape; a cover glass adjacent to the lead foil, where the cover glass includes a top surface, a bottom surface, and an opening, where the opening penetrates the top and bottom surfaces of the cover glass; and a barrier material in the opening of the cover glass.

The photovoltaic module may have various optional features. For example, the barrier material may substantially fill the opening. The barrier material may include multiple layers. The barrier material may include a binding material and a solid object. The binding material may coat an inner perimeter of the opening, thereby substantially separating one or more portions of the inner perimeter from the solid object. The binding material may include EVA. The solid object may include a moisture-resistive material. The solid object may include an organic material or an inorganic material. The solid object may include a glass, for example, a soda-lime glass. The photovoltaic module may include a cord plate assembly positioned on the top surface of the cover glass.

In general, a method of manufacturing a photovoltaic module may also include depositing a semiconductor layer adjacent to a substrate; depositing a strip of double-sided tape adjacent to the semiconductor layer; depositing a lead foil adjacent to the strip of double-sided tape; positioning a cover glass adjacent to the lead foil, where the cover glass includes a top surface, a bottom surface, and an opening, where the opening penetrates the top and bottom surfaces of the cover glass; and depositing a barrier material in the opening of the cover glass.

The method may have various optional features. For example, the barrier material may substantially fill the opening. The barrier material may include multiple layers. The barrier material may include a binding material and a solid object. The binding material may coat an inner perimeter of the opening, thereby substantially separating one or more portions of the inner perimeter from the solid object. The binding material may include EVA. The solid object may include a moisture-resistive material. The solid object may include an organic material or an inorganic material. The solid object may include a glass, for example, a soda-lime glass. The method may include positioning a cord plate assembly on the top surface of the cover glass.

In general, a photovoltaic module may also include a substrate; a semiconductor layer adjacent to the substrate; a lead foil adjacent to the semiconductor layer; a cover glass adjacent to the lead foil, where the cover glass includes a top surface, a bottom surface, and an opening, where the opening penetrates the top and bottom surfaces of the cover glass; and a barrier material proximate to the opening, and for preventing moisture from contacting the semiconductor layer, where the barrier material includes a barrier lateral dimension and the opening includes an opening lateral dimension, where the barrier lateral dimension extends a distance at least substantially equivalent to the opening lateral dimension.

The photovoltaic module may have various optional features. For example, the barrier material may be positioned between the semiconductor layer and the cover glass of the photovoltaic module, where the barrier lateral dimension is greater than the opening lateral dimension. The barrier layer may include a strip of double-sided tape. The photovoltaic module may include a strip of double-sided tape between the semiconductor layer and the lead foil. The barrier layer may be positioned between the strip of double-sided tape and the semiconductor layer. The barrier layer may be positioned between the strip of double-sided tape and the lead foil. The barrier layer may include an insulative material. The photovoltaic module may include an insulative material. The barrier material may be positioned on a back contact metal, where the photovoltaic module includes the back contact metal. The barrier material may include an organic material, an oxide, or metal. The barrier material may include an adhesive. The barrier lateral dimension may extend a distance substantially equivalent to a lateral dimension of the photovoltaic module. The barrier lateral dimension may be greater than a moisture diffusion path length, where the moisture diffusion path length is defined by a length extending laterally away from a perimeter of the opening over which moisture is capable of diffusing. The barrier material may be positioned in the opening. The barrier material may substantially fill the opening. The barrier material may include a binding material and a solid object. The binding material may coat an inner perimeter of the opening, thereby substantially separating one or more portions of the inner perimeter from the solid object. The binding material may include EVA. The solid object may include an organic material, an inorganic material, or a glass. The photovoltaic module may include a cord plate assembly on the cover glass.

A photovoltaic module can include a transparent conductive oxide layer adjacent to a substrate and layers of semiconductor material. The layers of semiconductor material can include a bi-layer, which may include an n-type semiconductor window layer, and a p-type semiconductor absorber layer. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current, which combined with the resulting voltage from the electric field, creates power. The result is the conversion of photon energy into electric power. To preserve and enhance device performance, numerous layers can be positioned above the substrate in addition to the semiconductor window and absorber layers.

Photovoltaic modules can have lead foils to collect current from positive and negative contacts. The lead foils can exit through a hole in the back cover glass. The package may be sealed with a cord plate assembly, which may provide connection of the lead foil with external lead wires, mechanical hold of the lead wires, and sealing of the back cover glass opening against exposure to humidity from environmental exposure. The cord plate assembly may include multiple components, such as adhesive layers, housing components, etc. An additional barrier can be incorporated within the photovoltaic module to prevent moisture from seeping into the module. Humidity can penetrate the cord plate assembly either through degradation, failure of the cord plate, or diffusion of moisture through the packaging materials, causing moisture-induced degradation of the photovoltaic module.

A barrier material can be incorporated into the photovoltaic module to prevent moisture from contacting one more of the module layers, for example, a semiconductor layer. The barrier material may be incorporated within any suitable location of the photovoltaic module to provide an effective barrier to moisture. For example, the barrier material may be deposited onto one of the semiconductor layers, or a back contact layer. Alternatively, the barrier material may be incorporated within an opening or hole in the cover glass. The barrier material may be substantially adhesive. For example, the barrier material may include a double-sided strip of tape. The barrier material may also include an insulative material. The barrier material may include any suitable material, including, for example, any suitable multilayered structure, organic or inorganic material, oxide, or metal, as well as any suitable water-resistant material. The barrier material may also include a binding material and a solid object. The solid object may include any suitable material, including, for example, any suitable moisture-resistive material or any organic or inorganic material. For example, the solid object may include a glass, for example, a soda-lime glass. Any moisture penetrating the cord plate assembly would have to diffuse along the binding material, significantly reducing the amount of moisture making contact with the photovoltaic device.

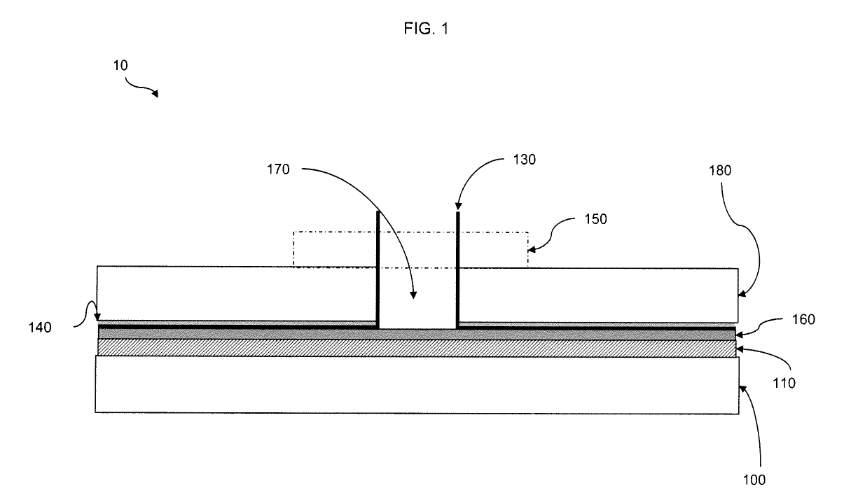

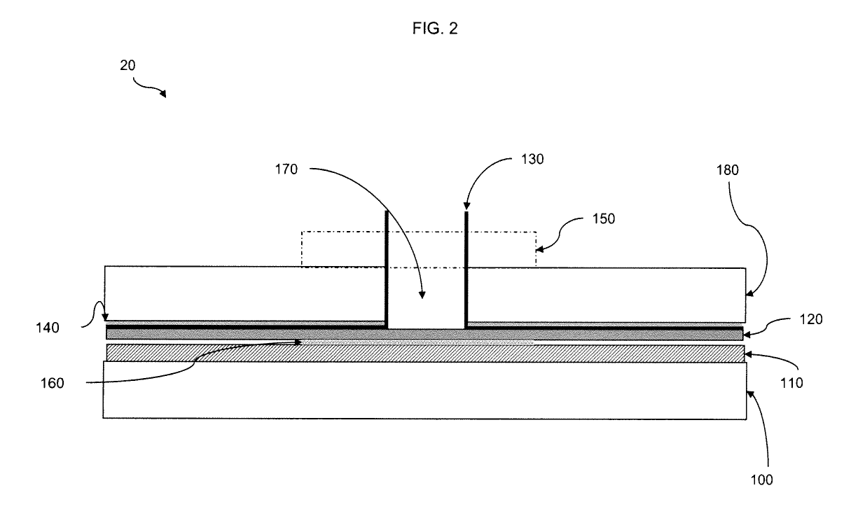

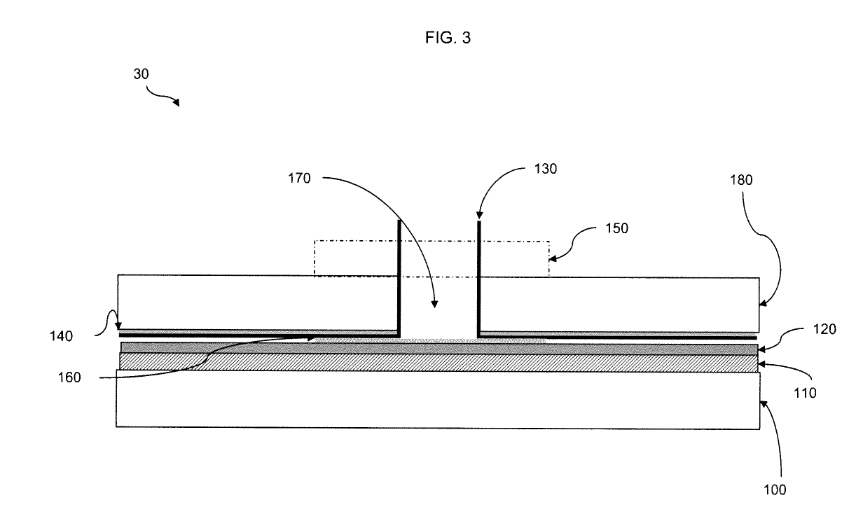

Referring to FIG. 1, a photovoltaic module 10 may include one or more layers 110 on a substrate 100. One or more layers 110 may include one or more photovoltaic device layers, including, for example, one or more semiconductor layers. One or more layers 110 may also include a transparent conductive oxide layer which may be part of a transparent conductive oxide stack, on top of which one or more semiconductor layers may be deposited. One or more layers 110 may also include a back contact, which may include any suitable contact metal. A barrier material 160 may be deposited onto one or more layers 110, for example, directly on a semiconductor or back contact metal of photovoltaic module 10. Barrier material 160 may include an adhesive. For example, barrier material 160 may include a strip of double-sided tape as shown in FIG. 1, with lead foil 130 and interlayer 140 deposited thereon. Interlayer 140 may include any suitable material, including, for example, EVA. An opening 170 may be formed in back support 180, through which lead foils 130 can be fed to connect with lead wires from cord plate assembly 150. Back support 180 may include any suitable material, including a glass, for example, a soda-lime glass. Back support 180 may include a back cover glass. Barrier material 160 can prevent one or more components of photovoltaic module 10 from being exposed to moisture in the event that cord plate assembly 150 fails to do so, either through degradation of cord plate assembly 150 or through diffusion through packaging materials. Barrier material 160 may include any suitable material, including, for example, any suitable organic material, oxide, or metallic layer, as well as any suitable water-resistant material. Barrier material 160 may include multiple layers. Referring to FIG. 2, a photovoltaic module 20 can include a barrier material 160 adjacent to one or more layers 110, with double-sided tape 120 positioned above. Alternatively, barrier material 160 can be positioned above double-sided tape 120, and lead foil 130 can be deposited thereafter, as shown in FIG. 3. The lateral dimensions of barrier material 160 may extend wider than opening 170 of back support 180. For example, the lateral dimensions of barrier material 160 may extend to substantially the same length and/or width as photovoltaic module 10. The larger the dimensions of barrier material 160, the larger the diffusion path for moisture. Barrier material 160 may include a barrier lateral dimension that is greater than the path length over which moisture is capable of diffusing into the photovoltaic module, where the path length extends laterally from the opening 170 of the photovoltaic module.

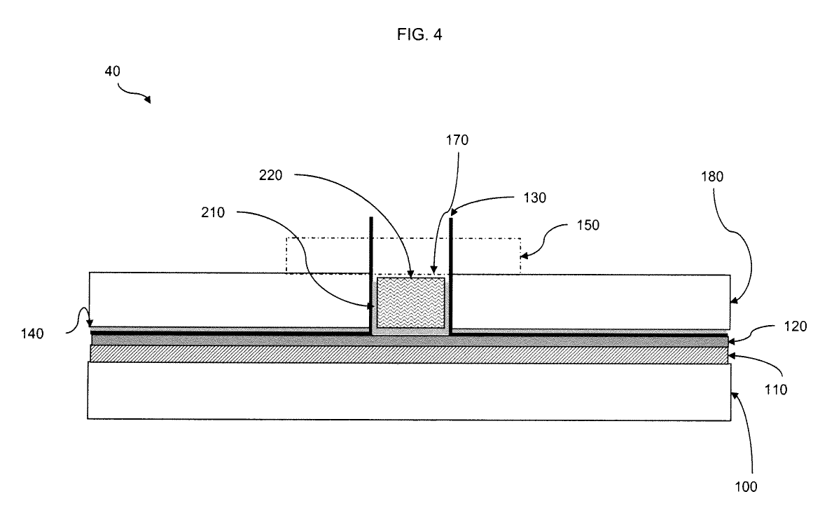

Barrier material 160 may be incorporated within any suitable location of the photovoltaic module. Referring to FIG. 4, by way of example, a photovoltaic module 40 may include a barrier material including a binding material 210 and a solid object 220. Binding material 210 may include any suitable material, including, for example, EVA. Binding material 210 can coat an inner perimeter of opening 170, and solid object 220 can be deposited into opening 170 thereafter. Binding material 210 can prevent direct contact between solid object 220 and the inner perimeter of opening 170. Solid object 220 may include any moisture-resistive material, including, for example, any suitable organic or inorganic material. Solid object 220 may include a glass, for example, a soda-lime glass. In the event that moisture penetrates through cord plate assembly 150, the moisture would have to diffuse along binding material 210, thereby significantly reducing the amount of moisture contacting one or more layers 110.

Photovoltaic devices/modules fabricated using the methods discussed herein may be incorporated into one or more photovoltaic arrays. The arrays may be incorporated into various systems for generating electricity. For example, a photovoltaic module may be illuminated with a beam of light to generate a photocurrent. The photocurrent may be collected and converted from direct current (DC) to alternating current (AC) and distributed to a power grid. Light of any suitable wavelength may be directed at the module to produce the photocurrent, including, for example, more than 400 nm, or less than 700 nm (e.g., ultraviolet light). Photocurrent generated from one photovoltaic module may be combined with photocurrent generated from other photovoltaic modules. For example, the photovoltaic modules may be part of a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A photovoltaic module comprising:
a substrate;
a semiconductor layer adjacent to the substrate;
a lead foil adjacent to the semiconductor layer;
a cover glass adjacent to the lead foil, the cover glass comprising a top surface, a bottom surface, and an opening, wherein the opening penetrates the top and bottom surfaces of the cover glass, and the opening comprises an opening lateral dimension; and
a barrier layer between the cover glass and the semiconductor layer, and comprising a barrier lateral dimension, wherein the barrier lateral dimension is greater than the opening lateral dimension.

2. The photovoltaic module of claim 1, wherein the barrier layer is positioned on a back contact metal, wherein the photovoltaic module comprises the back contact metal.

3. The photovoltaic module of claim 1, wherein the barrier layer is effective as a moisture barrier.

4. The photovoltaic module of claim 1, wherein:
the barrier layer comprises a strip of double-sided tape;
the barrier layer comprises an insulative material;
the barrier layer comprises multiple layers;
the barrier layer comprises an organic material;
the barrier layer comprises an oxide;
the barrier layer comprises metal; or
the barrier layer comprises an adhesive.

5. The photovoltaic module claim 1, wherein:
the barrier lateral dimension extends a distance substantially equivalent to a lateral dimension of the photovoltaic module; or
the barrier lateral dimension is greater than a moisture diffusion path length, wherein the moisture diffusion path length is defined by a length extending laterally away from a perimeter of the opening over which moisture is capable of diffusing.

6. The photovoltaic module of claim 1, further comprising a strip of double-sided tape between the semiconductor layer and the lead foil.

7. The photovoltaic module of claim 1, further comprising an insulative material.

8. The photovoltaic module of claim 1, further comprising a cord plate assembly positioned on the top surface of the cover glass.

9. The photovoltaic module of claim 6, wherein:
the barrier layer is positioned between the strip of double-sided tape and the semiconductor layer; or
the barrier layer is positioned between the strip of double-sided tape and the lead foil.

10. A method of manufacturing a photovoltaic module, the method comprising:
depositing a semiconductor layer adjacent to a substrate;
depositing a lead foil adjacent to the semiconductor layer;
positioning a cover glass adjacent to the lead foil, the cover glass comprising a top surface, a bottom surface, and an opening, wherein the opening penetrates the top and bottom surfaces of the cover glass, and the opening comprises an opening lateral dimension; and
depositing a barrier layer between the cover glass and the semiconductor layer, wherein the barrier layer comprises a barrier lateral dimension, wherein the barrier lateral dimension is greater than the opening lateral dimension.

11. The method of claim 10, further comprising:
positioning a strip of double-sided tape between the semiconductor layer and the lead foil;
positioning an insulative material adjacent to the semiconductor layer; or
positioning a cord plate assembly on the top surface of the cover glass.

12. The method of claim 11, wherein the step of depositing a barrier layer comprises:
placing the barrier layer between the strip of double-sided tape and the semiconductor layer;
placing the barrier layer between the strip of double-sided tape and the lead foil; or
placing the barrier layer on a back contact metal, wherein the photovoltaic module comprises the back contact metal.

13. A photovoltaic module comprising:
a substrate;
a semiconductor layer adjacent to the substrate;
a strip of double-sided tape adjacent to the semiconductor layer;
a lead foil adjacent to the strip of double-sided tape;
a cover glass adjacent to the lead foil, the cover glass comprising a top surface, a bottom surface, and an opening, wherein the opening penetrates the top and bottom surfaces of the cover glass; and
a barrier material in the opening of the cover glass.

14. The photovoltaic module of claim 13, wherein:
the barrier material substantially fills the opening;
the barrier material comprises multiple layers; or
the barrier material comprises a binding material and a solid object.

15. The photovoltaic module of claim 14, wherein:
the binding material coats an inner perimeter of the opening, thereby substantially separating one or more portions of the inner perimeter from the solid object; or
the binding material comprises EVA.

16. The photovoltaic module of claim 14, wherein:
the solid object comprises a moisture-resistive material;
the solid object comprises an organic material;
the solid object comprises an inorganic material;
the solid object comprises a glass; or
the solid object comprises a soda-lime glass.

17. The photovoltaic module of claim 14, further comprising a cord plate assembly positioned on the top surface of the cover glass.

18. A method of manufacturing a photovoltaic module, the method comprising:
depositing a semiconductor layer adjacent to a substrate;
depositing a strip of double-sided tape adjacent to the semiconductor layer;
depositing a lead foil adjacent to the strip of double-sided tape;
positioning a cover glass adjacent to the lead foil, the cover glass comprising a top surface, a bottom surface, and an opening, wherein the opening penetrates the top and bottom surfaces of the cover glass; and
depositing a barrier material in the opening of the cover glass.

19. The method of claim 18, wherein:
the barrier material substantially fills the opening;
the barrier material comprises multiple layers; or
the barrier material comprises a binding material and a solid object.

20. The method of claim 19, wherein:
the binding material coats an inner perimeter of the opening, thereby substantially separating one or more portions of the inner perimeter from the solid object; or
the binding material comprises EVA.

21. The method of claim 19, wherein:
the solid object comprises a moisture-resistive material;
the solid object comprises an organic material;
the solid object comprises an inorganic material;
the solid object comprises a glass; or
the solid object comprises a soda-lime glass.

22. A photovoltaic module comprising:
a substrate;
a semiconductor layer adjacent to the substrate;
a lead foil adjacent to the semiconductor layer;
a cover glass adjacent to the lead foil, the cover glass comprising a top surface, a bottom surface, and an opening, wherein the opening penetrates the top and bottom surfaces of the cover glass; and
a barrier material proximate to the opening, and for preventing moisture from contacting the semiconductor layer, the barrier material comprising a barrier lateral dimension and the opening comprising an opening lateral dimension,
wherein the barrier lateral dimension extends a distance at least substantially equivalent to the opening lateral dimension.

23. The photovoltaic module of claim 22, wherein:
the barrier material is positioned between the semiconductor layer and the cover glass of the photovoltaic module, and wherein the barrier lateral dimension is greater than the opening lateral dimension; or
the barrier material is positioned in the opening.

24. The photovoltaic module of claim 23, wherein the barrier layer comprises a strip of double-sided tape.

25. The photovoltaic module of claim 23, further comprising a strip of double-sided tape between the semiconductor layer and the lead foil.

26. The photovoltaic module of claim 23, further comprising an insulative material.

27. The photovoltaic module of claim 23, further comprising a cord plate assembly on the cover glass.

28. The photovoltaic module of claim 25, wherein:
the barrier layer is positioned between the strip of double-sided tape and the semiconductor layer; or
the barrier layer is positioned between the strip of double-sided tape and the lead foil.

29. The photovoltaic module of claim 23, wherein the barrier layer comprises an insulative material.

30. The photovoltaic module of claim 23, wherein:
the barrier lateral dimension extends a distance substantially equivalent to a lateral dimension of the photovoltaic module; or
the barrier lateral dimension is greater than a moisture diffusion path length, wherein the moisture diffusion path length is defined by a length extending laterally away from a perimeter of the opening over which moisture is capable of diffusing.

31. The photovoltaic module of claim 22, wherein:
the barrier material is positioned on a back contact metal, wherein the photovoltaic module comprises the back contact metal; or
the barrier material substantially fills the opening.

32. The photovoltaic module of claim 23, wherein:
the barrier material comprises an organic material, an oxide, or metal;
the barrier material comprises an adhesive; or
the barrier material comprises a binding material and a solid object.

33. The photovoltaic module of claim 32, wherein:
the binding material coats an inner perimeter of the opening, thereby substantially separating one or more portions of the inner perimeter from the solid object; or
the binding material comprises EVA.

34. The photovoltaic module of claim 32, wherein the solid object comprises an organic material, an inorganic material, or a glass.
